(19) United States
(12) Patent Application Publication
(10) Pub. No.: US 2026/0052704 A1
(43) Pub. Date: Feb. 19, 2026

(54) MAGNETORESISTIVE MEMORY WITH INTEGRATED SELECTORS

(71) Applicant: COMMISSARIAT À L'ENERGIE ATOMIQUE ET AUX ENERGIES ALTERNATIVES, PARIS (FR)

(72) Inventors: Bernard VIALA, GRENOBLE (FR); Denys LY, GRENOBLE (FR)

(21) Appl. No.: 19/295,785

(22) Filed: Aug. 11, 2025

(30) Foreign Application Priority Data
Aug. 13, 2024 (FR) 2408895

(51) Int. Cl. H10B 61/00; G11C 11/16; H10N 50/10; H10N 50/85

(52) U.S. Cl. CPC H10B 61/20; G11C 11/161; G11C 11/1673; G11C 11/1675; H10N 50/10; H10N 50/85

(57) ABSTRACT

A magnetoresistive memory cell includes a pillar forming a magnetic tunnel junction and a write track made of a spin Hall effect material or an orbital Hall effect material; a support layer made of a material with a configurable metal-insulator transition; a first electrode arranged on the support layer; the part of the support layer confined between the first electrode and the write track forming a first selector; a second electrode arranged on the support layer; the part of the support layer confined between the second electrode and the write track forming a second selector.

### CROSS-REFERENCE TO RELATED APPLICATION

This application claims priority to foreign French patent application No. FR 2408895, filed on Aug. 13, 2024, the disclosure of which is incorporated by reference in its entirety.

### FIELD OF APPLICATION

The present invention relates to the field of non-volatile memory circuit design and more particularly to magnetoresistive spin-orbit or Hall-orbit memory cells, the implementation of dense memory arrays and their read and write programming.

### BACKGROUND

Magnetoresistive Random Access Memory (MRAM) with Spin-Orbit-Torque (SOT) transfer is an advanced non-volatile memory that uses magnetic mechanisms to store data. It is based on magnetic tunnel junctions of which the resistance varies according to the orientation of the magnetic layers. Unlike conventional MRAM, SOT MRAM uses spin-orbit transfer, where currents through a track formed by materials with strong spin-orbit coupling induce switching of the magnetic state in a tunnel junction structure in contact with said track. This enables faster switching, better endurance and increased energy efficiency. SOT MRAM technology is ideal for applications requiring fast, non-volatile and durable memory. This durability is achieved because writing does not require the write current to pass through the magnetic tunnel junction pillar.

However, the memory cell of a SOT MRAM is different from standard non-volatile memories such as PCRAM, CBRAM, FeRAM and STT MRAM, which are two-port electronic devices consisting of a resistive element (1R) and a transistor (1T) with merged write and read paths (denoted 1T1R). The memory cell of a SOT MRAM is a three-port electronic device comprising a magnetoresistive element (1R), a write track (SOT) and two transistors (2T) with separate write and read paths. This configuration, referred to as 2T1R, results in a lower integration density for SOT MRAM, which is inherently less compact. This configuration of the SOT-MRAM memory cell makes it incompatible with a crossbar matrix arrangement, because of the use of two transistors.

For standard non-volatile memories such as PCRAM, CBRAM and FeRAM, crossbar memories have been developed, connecting the memory points by two perpendicular metal lines to increase the density of the structure. They are written and read using specific voltages and currents based on Kirchhoff's laws. Memory point selection uses selectors(S) instead of transistors, making 1S1R memory cells much more compact. The selectors are voltage-controlled volatile Off/On nanoswitches. The selectors generally used for 1S1R memory cells are varistors formed by filament conductors made mainly of ZrO₂ or HfO₂ or by OTS (acronym for Ovionic Threshold Switches) phase-change conductors. These types of selectors are not compatible with MRAM memory cells, and more specifically SOT-MRAM, which have reduced voltage operating ranges. On the one hand, the voltage range of an MRAM memory cell is limited because of the low breakdown voltage of the tunnel barrier (from 1.3V to 2V); on the other hand, the above-mentioned selectors have an ON/OFF threshold voltage of the order of 5V.

There is also a need to design at least one matrix implementation of the new SOT-MRAM memory cell architecture and to define at least one suitable read/write programming enabling the new memory cell according to the invention to be implemented in an application framework.

The same need exists with the OTT (Orbital Transfer Torque) MRAM memory concept, which uses the injection of orbital moment currents instead of spin currents by replacing the tungsten write track SOT with an OTT track made, for example, of titanium. The invention is described for SOT-MRAM memory cells with a write track made of a material with a spin-orbit torque effect, but is also valid for Orbital Transfer Torque (OTT) MRAM memories. The advantages and features described for SOT-MRAM memory cells remain valid for OTT-MRAM memories.

### Prior Art/State of the Art Restrictions

The scientific publication [1] describes a solution which consists of replacing, in a SOT-MRAM memory cell, the read transistor when it is in series with the magnetic tunnel junction pillar with a diode. This is a 1S1T1R type structure. This solution has a disadvantage in terms of density, as the diodes are still too large in relation to the memory cell. In addition, the diode significantly increases the read energy because of the greater voltage drop across the diode.

U.S. Pat. No. 11,289,143B2 presents a SOT-MRAM memory cell in which the write transistor connected in series with the SOT track is replaced by a selector but the read transistor remains in series with the magnetic tunnel junction pillar. This is a 1S1T1R type structure. In the proposed memory cell, a write operation requires the write current to pass through half the SOT track and through the magnetic tunnel junction, which has two major drawbacks: a reduction in the durability of the memory cell because the current passes through the magnetic tunnel junction, which reduces its robustness, and a reduction in write efficiency (by the SOT effect) because the write current only passes through half the SOT track.

### Responding to the Problem and Providing a Solution

To overcome the limitations of existing solutions, the invention proposes a magnetoresistive spin-orbit memory cell with a 2S1R structure enabling dense memory structures to be produced. Memory cells comprise integrated selectors (also called nanoswitches) based on a layer made of a material with a configurable metal-insulator transition, preferably Mott oxides compatible with low voltages. Alternatively, integrated selectors based on 2D materials of the topological insulator type are possible.

In addition, the invention presents asynchronous write modes that exploit the hysteresis effect in the materials forming the selectors and minimize the number of control voltages required to perform a write. This considerably reduces the energy consumption of memory cells. The invention also offers several read modes compatible with the memory cell according to the invention.

In addition, the invention presents a plurality of memory matrix architectures based on the new memory cell and enabling the various write and read modes proposed by the invention to be implemented.

### SUMMARY/CLAIMS

The invention relates to a magnetoresistive memory cell comprising:
a pillar forming a magnetic tunnel junction and having an upper end for receiving a first control voltage and a lower end;
a write track made of a material with a spin Hall effect or a material with an orbital Hall effect; the pillar being arranged on said write track at its lower end;
a support layer made of a material having a configurable metal-insulator transition; the support layer having a first face and an opposite second face;
the write track being disposed on said first face;
a first electrode arranged on said second face and intended to receive a second control voltage; the part of the support layer confined between the first electrode and the write track having a conduction state configurable by the first and second control voltages so as to form a first selector having a high resistive state and a low resistive state;
a second electrode arranged on said second face and intended to receive a third control voltage; the part of the support layer confined between the second electrode and the write track having a conduction state configurable by the first and third control voltages so as to form a second selector having a high resistive state and a low resistive state.

According to a particular aspect of the invention, the support layer is made of Mott oxide or a topological insulator.

According to a particular aspect of the invention, the write track is in physical contact with said first face of the support layer.

According to a particular aspect of the invention, the support layer has a width greater than or equal to that of the write track.

According to a particular aspect of the invention, the write track is made of a spin Hall effect material chosen from beta phase tungsten or bismuth antimonide or a BiSbTe alloy.

According to a particular aspect of the invention, the write track is made of an orbital Hall effect material chosen from chromium or zirconium or titanium or vanadium or copper or manganese or molybdenum or ruthenium or aluminium or niobium or tungsten in alpha phase.

According to a particular aspect of the invention, the write track has a thickness of less than or equal to 20 nm, advantageously 10 nm and more advantageously 5 nm.

According to a particular aspect of the invention, the first and/or second selector has a resistance greater than or equal to 10 times the resistance of the write track when said selector is in a high resistive state.

According to a particular aspect of the invention, the first and/or second selector has a resistance greater than or equal to 10 times the resistance of the magnetic tunnel junction when said selector is in a high resistive state.

According to a particular aspect of the invention, the first and/or second selector has a resistance less than or equal to the resistance of the write track when said selector is in a low resistive state.

According to a particular aspect of the invention, the first and/or second selector has a resistance less than or equal to one tenth of the resistance of the magnetic tunnel junction when said selector is in a low resistive state.

According to a particular aspect of the invention, the magnetoresistive memory cell further comprises a control transistor; the source of said control transistor being connected to the upper end of the pillar.

According to a particular aspect of the invention, the magnetoresistive memory cell further comprises an attenuation transistor; the drain of said attenuation transistor being connected to the first electrode.

According to a particular aspect of the invention, the first and/or second selector is adapted to pass from a high resistive state to a low resistive state when the amplitude of the voltage across said selector is greater than a predetermined threshold voltage.

The invention also relates to a memory circuit comprising:
a memory matrix formed by a plurality of memory cells according to the invention;
a control circuit configured to generate the first control voltage, the second control voltage and the third control voltage.

According to a particular aspect of the invention, the control circuit is configured to perform a write operation on a memory cell of the matrix by applying:
a first control voltage of zero, a second control voltage greater than the predetermined threshold voltage and a third control voltage of zero to write a first logic state;
a first control voltage of zero, a second control voltage of zero and a third control voltage greater than the predetermined threshold voltage to write a second logic state complementary to the first logic state.

According to a particular aspect of the invention, the control circuit is configured to perform a write operation on a memory cell of the matrix by applying:
a first control voltage greater than the predetermined threshold voltage, a second control voltage equal to the first control voltage and a third control voltage of zero to write a first logic state;
a first control voltage greater than the predetermined threshold voltage, a second control voltage of zero and a third control voltage equal to the first control voltage to write a second logic state complementary to the first logic state.

According to a particular aspect of the invention, the control circuit is configured to perform a write operation on a memory cell of the matrix by applying:
a second control voltage greater than twice the predetermined threshold voltage; a first control voltage equal to half the second control voltage and a third control voltage of zero to write a first logic state;
a third control voltage greater than twice the predetermined threshold voltage; a first control voltage equal to half the third control voltage and a second control voltage of zero to write a second logic state complementary to the first logic state.

According to a particular aspect of the invention, the control circuit is configured to perform a read operation on a memory cell of the memory matrix by applying to it a second and a third control voltage greater than the predetermined threshold voltage and a first control voltage of zero.

According to a particular aspect of the invention:
the upper ends of the pillars of the memory cells belonging to the same column of the memory matrix are interconnected via a first conductive line intended to propagate the associated first control voltage;
the first electrodes of the memory cells belonging to the same row of the memory matrix are interconnected via a second conductive line intended to propagate the associated second control voltage;
the second electrodes of the memory cells belonging to the same row of the memory matrix are interconnected via a third conductive line designed to propagate the associated third control voltage.

According to a particular aspect of the invention:
the upper ends of the pillars of the memory cells belonging to the same column of the memory matrix are interconnected via a first conductive line intended to propagate the associated first control voltage;
the first electrodes of the memory cells belonging to the same row of the memory matrix are interconnected via a second conductive line intended to propagate the associated second control voltage;
the second electrodes of the memory cells belonging to the same column of the memory matrix are interconnected via a third conductive line intended to propagate the associated third control voltage.

According to a particular aspect of the invention:
the gates of the control transistors of the memory cells belonging to the same column of the memory matrix are interconnected via a first conductive line intended to propagate an associated selection signal;
the drains of the control transistors of the memory cells belonging to the same row of the memory matrix are interconnected via a second conductive line intended to propagate the associated first control voltage;
the first electrodes of the memory cells belonging to the same row of the memory matrix are interconnected via a third conductive line intended to propagate the associated second control voltage;
the second electrodes of the memory cells belonging to the same column of the memory matrix are interconnected via a fourth conductive line intended to propagate the associated third control voltage.

According to a particular aspect of the invention:
the upper ends of the pillars of the memory cells belonging to the same row of the memory matrix are interconnected via a first conductive line intended to propagate the associated first control voltage;
the sources of the attenuation transistors of the memory cells belonging to the same row of the memory matrix are interconnected via a second conductive line intended to propagate the associated second control voltage;
the second electrodes of the memory cells belonging to the same column of the memory matrix are interconnected via a third conductive line intended to propagate the associated third control voltage;
the gates of the attenuation transistors of the memory cells belonging to the same column of the memory matrix are interconnected via a fourth conductive line intended to propagate an associated selection signal.

According to a particular aspect of the invention:
the upper ends of the pillars of the memory cells belonging to the same column of the memory matrix are interconnected via a first conductive line intended to propagate the associated first control voltage;
the sources of the attenuation transistors of the memory cells belonging to the same row of the memory matrix are interconnected via a second conductive line intended to propagate the associated second control voltage;
the second electrodes of the memory cells belonging to the same row of the memory matrix are interconnected via a third conductive line intended to propagate the associated third control voltage;
the gates of the control transistors of the memory cells belonging to the same column of the memory matrix are interconnected via a fourth conductive line intended to propagate an associated selection signal.

### BRIEF DESCRIPTION OF THE DRAWINGS

Further features and advantages of the present invention will become apparent from the following description in relation to the following annexed drawings.

FIG. 1a shows a cross-section of a magnetoresistive spin-orbit memory cell according to the invention, in a first configuration.

FIG. 1b shows a cross-section of a magnetoresistive spin-orbit memory cell according to the invention, in a second configuration.

FIG. 1c shows an electrical diagram of a magnetoresistive spin-orbit memory cell according to the invention.

FIG. 2 shows a block diagram of a memory circuit according to the invention.

FIG. 3a illustrates the steps of a first write mode of the memory cell according to the invention.

FIG. 3b illustrates the steps of a second write mode of the memory cell according to the invention.

FIG. 3c illustrates the steps of a third write mode of the memory cell according to the invention.

FIG. 3d illustrates the steps of a first read mode of the memory cell according to the invention.

FIG. 3e illustrates the steps of a second read mode of the memory cell according to the invention.

FIG. 4a shows an electrical diagram of a memory matrix used in the memory circuit according to a first embodiment of the invention.

FIG. 4b shows an electrical diagram of a memory matrix used in the memory circuit according to a second embodiment of the invention.

FIG. 4c shows an electrical diagram of a memory matrix used in the memory circuit according to a third embodiment of the invention.

FIG. 4d shows an electrical diagram of a memory matrix used in the memory circuit according to a fourth embodiment of the invention.

FIG. 4e shows an electrical diagram of a memory matrix used in the memory circuit according to a fifth embodiment of the invention.

### DETAILED DESCRIPTION

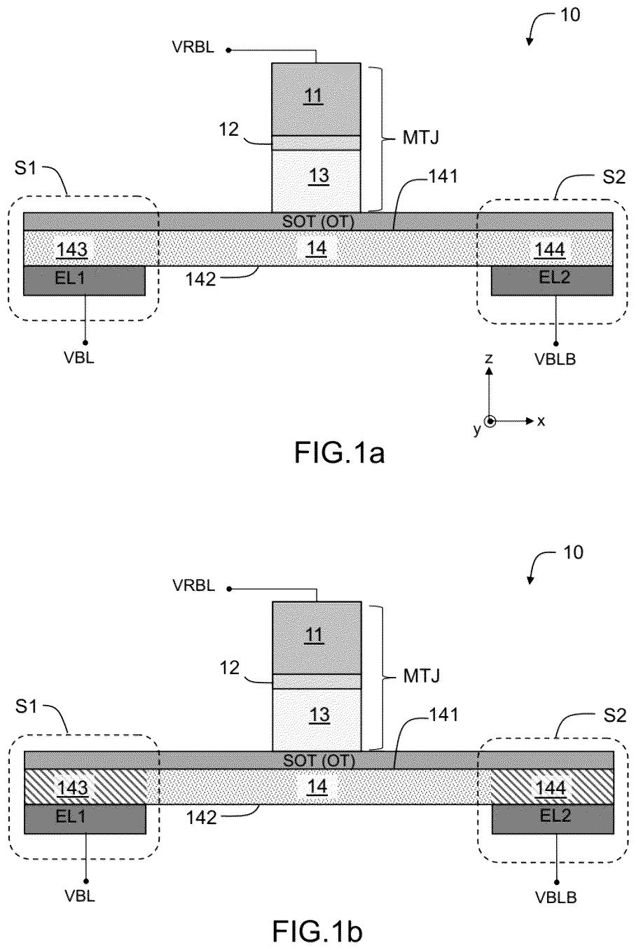

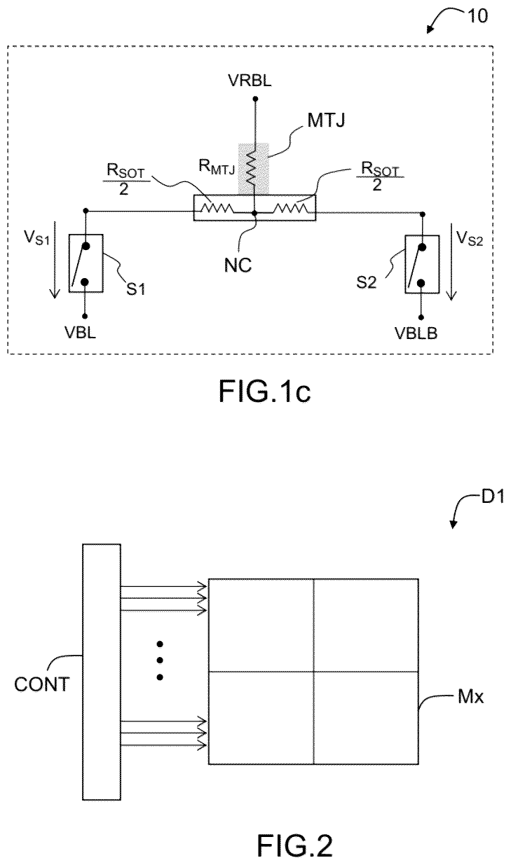

FIG. 1a shows a cross-sectional view of a magnetoresistive spin-orbit memory cell 10 according to the invention. The memory cell 10 comprises a magnetic tunnel junction MTJ, a write track SOT, a support layer 14, a first electrode EL1 and a second electrode EL2.

The magnetic tunnel junction MTJ is a magnetoresistive pillar comprising a stack of layers 11, 12, 13 which work together to enable data to be stored and read via manipulation of the magnetic properties. The stack comprises a first ferromagnetic reference layer 11 in which the direction of magnetic polarization is fixed and uniform. The stack further comprises a second ferromagnetic layer 13 in which the direction of magnetic polarization is variable. The stack further comprises a tunnel barrier layer 12 of oxide, such as MgO (magnesium oxide), confined between the first and second ferromagnetic layers 11, 13. This layer plays a crucial role in magnetoresistive tunnelling, allowing electrons to pass through by quantum tunnelling. The tunnel barrier layer 12 is less than 1 nm thick. The first ferromagnetic layer 11 is used as a reference to detect magnetization changes in the free ferromagnetic layer 13. For example, the first and second layers 11, 13 are made of materials such as CoFeB. The operating principle of the magnetoresistive pillar MTJ is based on the change in electrical resistance as a function of the magnetic bias orientation of the free ferromagnetic layer 13 relative to that in the reference ferromagnetic layer 11. When the magnetizations of the free and reference layers 11, 13 are parallel, the electrical resistance is low across the magnetic tunnel junction MTJ pillar. When the magnetizations are anti-parallel, the electrical resistance is high. This change in resistance is detected to read a memory state (bit 0 or 1). This change in resistance is caused to write a memory state (bit 0 or 1).

The magnetic tunnel junction MTJ rests on the write track SOT. The interface between the magnetic tunnel junction MTJ and the write track SOT is on the side of the free ferromagnetic layer 13. The direction of the stack forming the magnetic tunnel junction MTJ is orthogonal to the plane formed by the layer forming the write track SOT. The write track SOT is made of a spin Hall effect material (also known as a spin-orbit couple effect material), for example beta phase tungsten or bismuth antimonide or a stack of two layers, one made of tantalum and the other of tungsten, or a BiSbTe alloy. When a write current crosses the write track SOT in one direction, spin currents are generated and interact with the free ferromagnetic layer 13. This interaction enables the direction of magnetic polarization in the free ferromagnetic layer 13 to be controlled according to the direction of the write current in the write track SOT. Controlling the direction of magnetic polarization in the free ferromagnetic layer 13 makes it possible to modify the electrical resistance of the magnetic tunnel junction MTJ without injecting a write current into it, which considerably increases the robustness of the memory cell 10.

The write track SOT is arranged on a first face 141 of the support layer 14. The support layer 14 is made of a material with a metal-insulator transition, more particularly a Mott oxide. This type of material has a volatile resistive transition between a high resistive state and a low resistive state. This transition is activated thermally and/or electrically and/or optically. It consists of a non-permanent (volatile) phase change between a stable high-resistance semiconducting ortho-cline phase and a metastable low-resistance conducting rutile tetragonal phase. The low resistance state is maintained only under thermal, electrical or optical stimulation. The invention exploits electrical stimulation by applying an electric field. The thickness of the support layer 14 is between 5 nm and 100 nm.

The first electrode EL1 is arranged on a second face 142 of the support layer 14 opposite the first face 141. The first electrode EL1 is positioned below a first end of the write track SOT. The second electrode EL2 is arranged on the second face 142. The second electrode EL2 is positioned below a second end of the write track SOT opposite the first end. The pillar forming the magnetic tunnel junction MTJ is located between the first end and the second end. The first electrode EL1 and the second electrode EL2 are each made of an electrically conductive layer of metal for example, preferably tungsten or copper or titanium nitride.

Electrically, a first control voltage VRBL is applied to the upper end of the pillar forming the magnetic tunnel junction MTJ. A second control voltage VBL is applied to the first electrode EL1. A third control voltage VBLB is applied to the second electrode EL2.

The stack formed by the first electrode EL1, the zone 143 of the support layer 14 made of a material with a metal-insulator transition and the write track SOT locally forms a selector S1 of reduced dimensions. The selector S1 can be configured between a high resistive state R1 OFF and a low resistive state R1 ON by applying a voltage between the first electrode EL1 and the write track SOT, i.e. the first and second voltages VRBL, VBL. Similarly, the stack formed by the second electrode EL2, the zone 144 of the support layer 14 made of a material with a metal-insulator transition and the write track SOT locally forms a second selector S2 of reduced dimensions. The second selector S2 can be configured between a high resistive state R2_{OFF} and a low resistive state R2_{ON} by applying a voltage between the second electrode EL2 and the write track SOT, i.e. the first and third voltages VRBL, VBLB. For each selector among S1 and S2, activation (switching from R_{OFF} to R_{ON}) is triggered when the amplitude of the voltage across the selector exceeds a predetermined threshold voltage Vth. For example, for a support layer 14 made of vanadium oxide, the threshold voltage is equal to 0.6 V, which is compatible with the voltage operating ranges of a magnetoresistive memory cell.

Alternatively, the support layer 14 comprises a low-voltage (<1 V) topological insulator, for example molybdenum disulphide. A topological insulator is a material that has the advantageous property of behaving like an insulator internally (it does not conduct electricity through its volume), while having conductive surfaces or edges. This type of material is called “topological” because its surface conductive properties are protected by topological features of the material's electronic structure, which means that they are robust against disturbances such as impurities or structural defects.

The selectors S1, S2 can be activated simultaneously by means of the same control voltage (same amplitude and same sign) or independently by means of two separate control voltages (same amplitude and opposite signs). Depending on the sign of the applied voltage, it is therefore possible to control the direction in which the selectors pass, either upwards (from the associated electrode to the write track SOT) or downwards (from the write track SOT to the electrode). In this way a bipolar current can flow through the whole of the track SOT for writing with commands of opposite signs and a unipolar current can flow through the pillar MTJ after having covered half the track SOT for reading with commands of the same signs.

The write track SOT is in physical contact with said first face 141 of the support layer 14. The width of the support layer 14 is greater than or equal to that of the write track SOT, in the X direction. This provides a contact interface between the support layer 14 and the entire lower face of the write track SOT. The support layer 14 is thus shared between the two selectors S1, S2. The central zone of the support layer 14, which corresponds neither to zone 143 nor to zone 144, is always in the insulating state, which makes it possible to electrically isolate the first selector S1 from the second selector S2 and vice versa. This arrangement facilitates the memory cell manufacturing process since it is possible to maximize the ß phase in the write track SOT over the entire width of the memory cell with a single operation to grow the write track SOT.

FIG. 1a illustrates a cross-sectional view of the magnetoresistive spin-orbit memory cell 10, according to a first configuration in which S1 and S2 are each in a high resistive (off) state. FIG. 1b illustrates a cross-sectional view of the magnetoresistive spin-orbit memory cell 10, according to a second configuration in which S1 and S2 are each in a low resistive (on) state.

The use of Mott oxides, preferably vanadium oxide and niobium oxide, has several additional advantages in the context of the invention.

Firstly, a particular feature of Mott oxides is that the metallic state can be maintained once the transition has taken place, even when the control voltage falls below the threshold voltage Vth, provided that a residual current flow is possible. This residual current maintains a certain temperature in the crystal, which is necessary for the stability of the rutile phase. When this current becomes too low, in other words when the crystal cools sufficiently, the tetragonal phase takes over and all electrical conduction ceases. This feature will be exploited in the context of this invention to perform an “asynchronous” write operation in a memory cell 10 according to the invention.

Another advantage of using Mott oxides to produce the support layer 14 is the improvement in the spin-orbit coupling effect in the write track SOT. Obtaining the β phase in the write track requires a supply of oxygen in the tungsten lattice. In the absence of an oxygen source, the current a phase of the tungsten or a mixture of the two phases is obtained, which cancels out or limits the spin-orbit coupling effect in the write track SOT. This small amount of oxygen can be provided, for example, by contact with the Mott oxide support layer 14.

Mott oxides therefore offer two advantages:
on the one hand, the oxide nature of the support layer 14 makes it possible to maximize the B phase in the write track SOT (or even eliminate the a phase altogether) so as to improve spin-orbit coupling;
on the other hand, the volatile metal-insulator transient nature of Mott oxides means that the two selectors S1, S2 can act as compact nano-switches to improve the density of the memory cell.

In the embodiment shown in FIG. 1a, the stacking direction is as follows, starting from the substrate along the Z axis: the electrodes EL1, EL2 then the support layer 14 then the write track SOT then the pillar MTJ. Alternatively, the memory cell 10 can be produced in the opposite direction to the cell shown in FIG. 1a, starting from the substrate as the origin of the Z axis. The pillar faces downwards. The stacking direction is as follows, starting from the substrate along the Z axis: the pillar MTJ facing downwards, then the write track SOT, then the support layer 14, then the electrodes EL1, EL2 on the upper surface. The downward-facing pillar MTJ is encapsulated in a dielectric layer.

Alternatively, the memory cell 10 according to the invention is a

magnetoresistive memory cell exploiting the orbital Hall effect. This embodiment differs from the embodiment shown in FIG. 1a in that the write track is configured to generate an orbital moment current from a charge current and not a spin current. The advantage of a write path separate from the read path is retained. Writing is done by converting the charge current into an orbital moment current which has a similar ability to the spin current to exert a torque on the magnetization of a magnetic layer. This is known as the orbital Hall effect (OHE) and differs from the spin Hall effect. Orbital Hall effect writing improves the characteristics of magnetic memories. The structure of an orbital Hall effect device is similar to that of a spin-orbit device, with the difference that the write track, also known as the “OT” track (Orbital Torque), is a track configured to generate a current of orbital moments from a current of charges. Orbital moments do not allow a torque to be applied to a magnetization at the pillar MTJ. One of two mechanisms may be required. The action of orbital moments on magnetization may be due to spin-orbital entanglement and/or part of the orbital moment current is converted to spin current at the junction of the pillar MTJ, the latter applying torque to a magnetization at the pillar MTJ. In the case of an orbital Hall effect memory cell, the write track OT is made of chromium or zirconium or titanium or vanadium or copper or manganese or molybdenum or ruthenium or aluminium or niobium or tungsten in alpha phase.

FIG. 1c shows an electrical diagram of the magnetoresistive spin-orbit memory cell 10 according to the invention. The first selector S1 is modelled by a switch controlled by the potential difference VS1. When the first selector S1 is in an on state, it is assimilated to a resistor R1_{ON} and when it is in an off state to a resistor R1_{OFF}. The second selector S2 is modelled by a switch controlled by the potential difference VS2. When the second selector S2 is in an on state it is assimilated to a resistor R2_{ON} and when it is in an off state to a resistor R2_{OFF}. The portion of the write track SOT located between the first selector S1 and the base of the pillar MTJ is modelled by a resistor R_{SOT}/2 where R_{SOT} is the equivalent electrical resistance of the write track. Symmetrically, the portion of the write track SOT located between the second selector S2 and the base of the pillar MTJ is modelled by a resistor R_{SOT}/2. The two resistors R_{SOT}/2 are connected in series, and their common node NC is a central node located at the base of the pillar MTJ. The pillar MTJ is modelled by a variable resistor RMTJ according to the binary data “1” or “0” stored in the MTJ memory cell. It is assumed that R1_{OFF}=R2_{OFF}=R_{OFF} and that R1_{ON}=R2_{ON}=R_{ON}.

The electrical behaviour of each selector S1, S2 is defined by the following three parameters: the on-state resistance R_{ON}, the off-state resistance R_{OFF} and the threshold voltage Vth. These three parameters can be modulated by modifying the composition of the support layer 14. According to a particular aspect of the invention, at least the zones 143 and 144 of the support layer 14 are doped with chromium, iron, aluminium or titanium atoms to lower the value of the threshold voltage Vth and the on-state resistance R_{ON} and to increase the off-state resistance R_{OFF}. According to a particular aspect of the invention, at least the zones 143 and 144 of the support layer 14 are doped with titanium or tungsten atoms to increase the value of the threshold voltage Vth and the on-state resistance R_{ON} and to decrease the off-state resistance R_{OFF}.

During a write operation, a write current i_{w} is injected through the write track SOT from the first electrode EL1 to the second electrode EL2 or vice versa. The write current i_{w} does not pass through the pillar MTJ and does not depend on the resistive state R_{MTJ} of said pillar. The write current i_{w} depends on the ratio R_{ON}/R_{SOT}. During a read operation, a read current iᵣ is injected through the pillar MTJ from the first electrode EL1 and/or the second electrode EL2. The read current iᵣ depends on the ratio R_{ON}/R_{MTJ}.

The composition and dimensioning of at least the parts 143, 144 of the support layer 14 are chosen so as to obtain the following inequalities:
R_{ON}<R_{SOT} in order to have a write current i_{w} with an amplitude sufficient to modify the magnetic polarization in the pillar MTJ, more advantageously R_{ON}≤0.1×R_{SOT}; an amplitude sufficient for writing is generally greater than 100 μA.
R_{ON}<0.1×R_{MTJ} to obtain a read current iᵣ with an amplitude sufficient to determine the resistive state of the MTJ magnetoresistive junction; an amplitude sufficient for reading is generally greater than 10 μA.
R_{OFF}≥10×R_{SOT} in order to be able to switch the selectors S1, S2 from an off state to an on state during a write operation, more advantageously R_{OFF}≥50×R_{SOT};
R_{OFF}≥10×R_{MTJ} in order to be able to switch the selectors S1, S2 from an off state to an on state during a read operation, more advantageously R_{OFF}≥100×R_{MTJ}.

FIG. 2 illustrates a block diagram of a memory circuit D1 according to the invention comprising a memory matrix Mx formed by a plurality of memory cells 10 according to the invention and a control circuit CONT configured to generate at least the first control voltage VRBL, the second control voltage VBL and the third control voltage VBLB according to the choice of arrangement of the matrix Mx.

The memory cell 10 according to the invention is compatible with several write and read modes, which will be described in detail in the next section.

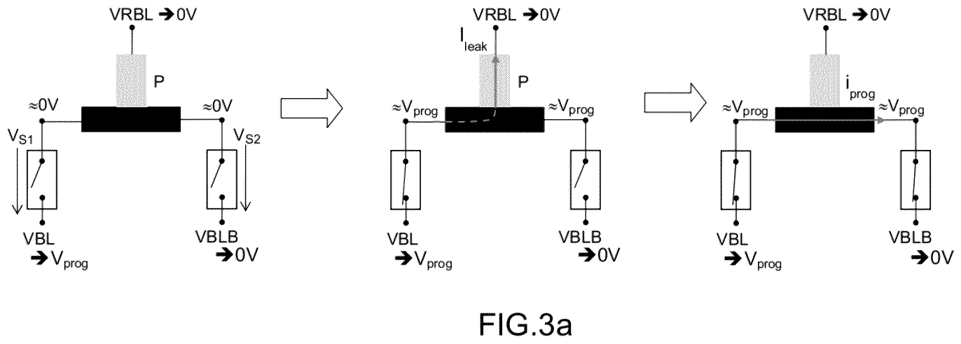

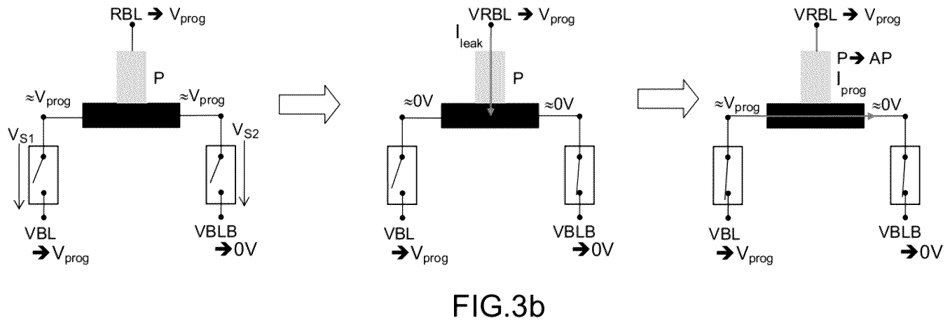

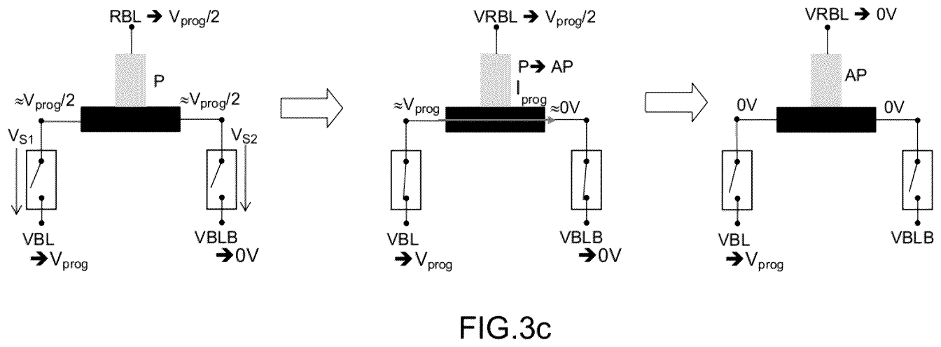

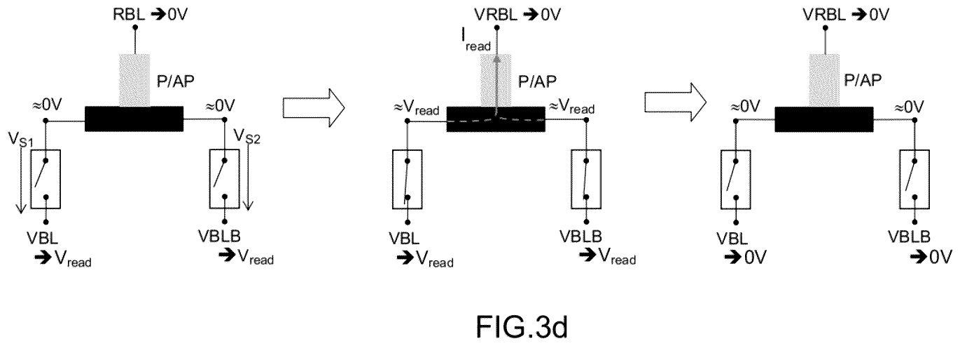

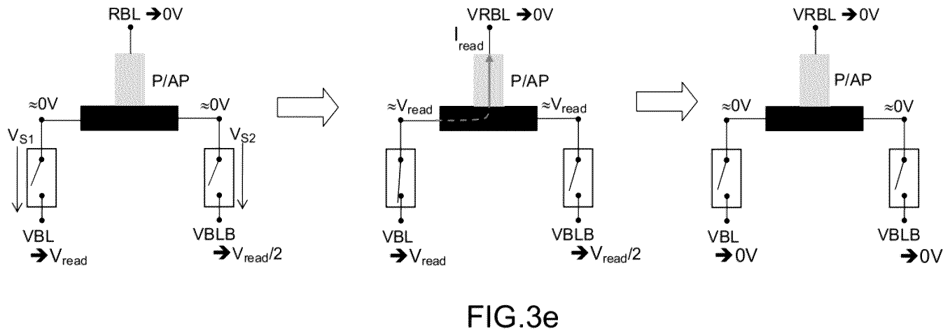

FIG. 3a illustrates the steps of a first write mode of the memory cell 10 according to the invention. Initially, the two selectors S1, S2 are in the off state. The control circuit CONT is configured to apply at the same time: a first zero control voltage VRBL to the upper end of the pillar MTJ, a second control voltage VBL=V_{prog} such that V_{prog}>Vth and a third zero control voltage VBLB. The zero potential is propagated through the pillar MTJ to the write track SOT. The first selector thus sees a voltage +V_{prog} greater than the threshold voltage at its terminals and switches to an on state, thus connecting the write track SOT to the first electrode EL1, which supplies the write voltage +V_{prog}. During a transient period, a leakage current will flow through the pillar MTJ. The leakage current is, for example, less than 80 μA and therefore does not accidentally modify the resistive state of the pillar MTJ and does not exceed the breakdown current of the magnetic tunnel junction. During this transient period, the potential +V_{prog} is also gradually established at the other end of the write track SOT located at the second selector S2, which thus sees a voltage −V_{prog} at its terminals with an amplitude greater than the threshold voltage Vth. The end of the transient mode corresponds to the switching of the second selector S2 under the action of the voltage −V_{prog} propagated by the write track SOT to allow the write current to be established from the first electrode EL1 to the second electrode EL2. The advantage of the first write mode according to the invention is that it is possible to write to the memory cell 10 by applying a single non-zero write voltage +V_{prog} to the first electrode EL1. Finally, the second control voltage VBL is progressively reset to zero to end the operation. It was thus possible to pass a write current from the first electrode EL1 to the second electrode EL2 through the write track SOT to write a first logic state “0”, for example.

To write a complementary logic state “1”, it is sufficient to apply a first control voltage VRBL of zero to the upper end of the pillar MTJ, a second control voltage VBL of zero and a third control voltage VBLB=V_{prog} such that V_{prog}>Vth. Symmetrically, by the same mechanism described, a write current is obtained from the second electrode EL2 to the first electrode EL1 through the write track SOT in order to write a second logic state “1”.

By way of an illustrative and non-limiting example, if the Mott oxide chosen is vanadium oxide, the threshold voltage is equal to 0.6V and the write voltage V_{prog}=0.7V to obtain a write current greater than 100 μA, advantageously greater than 500 μA.

Advantageously, the two selectors S1, S2 remain in the on state for an additional period of time thanks to a particular feature of the Mott oxides used to produce the two selectors S1, S2. During the downward transition, as long as a non-zero voltage persists at the terminals of S1, S2, it ensures the passage of a residual ohmic current by minimal heating. The residual ohmic current sufficiently maintains the thermal stability of the conductive rutile phase in zones 143, 144. When the control voltage VBL is reduced to zero, the metal/insulator downward transition is shifted well below the threshold voltage Vth. This is referred to as an “asynchronous” write operation.

FIG. 3b illustrates the steps of a second mode of writing the memory cell 10 according to the invention. The second write mode according to the invention is also an “asynchronous” write operation. Initially, the two selectors S1, S2 are in the off state. The control circuit CONT is configured to apply at the same time: a first control voltage VRBL=V_{prog} such that V_{prog}>Vth to the upper end of the pillar MTJ, a second control voltage VBL=V_{prog} and a third control voltage VBLB of zero. The potential V_{prog} propagates through the pillar to the write track SOT. The second selector S2 thus sees a voltage VS2=VBLB−VSOT=−V_{prog} greater than the threshold voltage at its terminals and switches to an on state, thus connecting the write track SOT to the second electrode EL2 connected to electrical earth GND. During a transient period, a leakage current will flow through the pillar MTJ to be evacuated by the electrode EL2. The leakage current is, for example, less than 80 μA and therefore does not accidentally modify the resistive state of the pillar MTJ and does not exceed the breakdown current of the magnetic tunnel junction. During this transient period, the zero voltage (GND) is also gradually established at the other end of the write track SOT located at the level of the first selector S1, which thus sees at its terminals a voltage +V_{prog} having an amplitude greater than the threshold voltage Vth. The end of the transient regime corresponds to the switching of the first selector S1 under the action of the potential difference VS1=VBL−V_{SOT}=+V_{prog}−0 to allow the write current to be established from the first electrode EL1 to the second electrode EL2. Finally, all the control voltages VBL and VRBL are progressively reset to zero to end the write operation. It was thus possible to pass a write current from the first electrode EL1 to the second electrode EL2 through the write track SOT to write a first logic state “0”, for example.

To write a complementary logic state “1”, it is sufficient to apply a first control voltage VRBL=V_{prog} such that V_{prog}>Vth to the upper end of the pillar MTJ, a second control voltage VBL of zero and a third control voltage VBLB=V_{prog}. Symmetrically, using the same mechanism described, a write current is obtained from the second electrode EL2 to the first electrode EL1 through the write track SOT in order to write a second logic state “1”.

FIG. 3c illustrates the steps of a third “synchronous” write mode of the memory cell 10 according to the invention. This mode is compatible with a support layer 14 which does not have a hysteresis effect, as for example in the case where said support layer 14 is doped with an additional element (Cr, Al, Fe, W, Mo, Ta, Ru, etc.) or produced by epitaxy. This write mode is also compatible with a support layer 14 comprising a topological insulator, as for example in MoS2.

Initially, the two selectors S1, S2 are in the off state. The control circuit CONT is configured to apply at the same time: a first control voltage VRBL=V_{prog}/2 such that V_{prog}>2× Vth to the upper end of the pillar MTJ, a second control voltage VBL=V_{prog} and a third control voltage VBLB=0. The potential V_{prog}/2 propagates through the pillar to the write track SOT. The first selector S1 thus sees a voltage VS1=VBL −V_{SOT}=V_{prog}−V_{prog}/2=+V_{prog}/2 greater than the threshold voltage at its terminals and switches to an on state thus connecting the write track SOT to the first electrode EL1. The second selector S2 thus sees at its terminals a voltage VS2=VBLB−V_{SOT}=0−V_{prog}/2=−V_{prog}/2 having an amplitude greater than the threshold voltage and switches to an on state thus connecting the write track SOT to the second electrode EL2 connected to earth GND. Following simultaneous activation of the two selectors S1, S2, a write current is established through the write track SOT from the first electrode EL1 to the second electrode EL2 to write a first logic state “0”, for example. Finally, all the control voltages VBL, VBLB and VRBL are progressively reset to zero and the selectors go to an off state to end the operation.

To write a complementary logic state “1” according to the third write mode, the control means CONT are configured to apply at the same time: a first control voltage VRBL=V_{prog}/2 such that V_{prog}>2× Vth to the upper end of the pillar MTJ, a second control voltage VBL=0 and a third control voltage VBLB=V_{prog}. A write current is obtained which flows through the write track SOT from the second electrode EL2 to the first electrode EL1.

Table 1 summarizes the different write modes according to the invention compatible with the memory cell 10:

| Write mode | Logic state | condition | VRBL | VBL | VBLB |
|---|---|---|---|---|---|
| 1^{st} mode | 0 | V_{prog} > Vth | 0 | V_{prog} | 0 |
| 1^{st} mode | 1 | V_{prog} > Vth | 0 | 0 | V_{prog} |
| 2^{nd} mode | 0 | V_{prog} > Vth | V_{prog} | V_{prog} | 0 |
| 2^{nd} mode | 1 | V_{prog} > Vth | V_{prog} | 0 | V_{prog} |
| 3^{rd} mode | 0 | V_{prog} > 2xVth | ½ V_{prog} | V_{prog} | 0 |
| 3^{rd} mode | 1 | V_{prog} > 2xVth | ½ V_{prog} | 0 | V_{prog} |

The first and second write modes are asynchronous (delayed activation of the selectors S1, S2), while the third mode is synchronous (simultaneous activation of the selectors S1, S2). Each write mode has particular advantages.

“Asynchronous” modes are advantageous because they allow the write voltage to be minimized by setting V_{prog} only 20% higher than the switching threshold voltage of the selectors S1, S2. The memory cell provides sufficient write current, greater than 500 μA for example, with very little leakage current in the pillar MTJ. Both asynchronous and synchronous modes generate sufficient write current levels. In terms of energy, asynchronous write modes are the most advantageous because they reduce write power consumption by half and keep control voltages below 1 V. On the other hand, the third synchronous write mode minimizes leakage currents through the pillar MTJ thanks to the simultaneous activation of the selectors S1, S2.

FIG. 3d illustrates the steps of a first mode of reading the memory cell 10 according to the invention. The control circuit CONT is configured to apply at the same time: a second control voltage VBL=V_{read} such that V_{read}>Vth, a third control voltage VBLB=V_{read} and a first control voltage VRBL of zero to the upper end of the pillar MTJ. The two selectors S1, S2 simultaneously switch to an on state and the potential V_{read} is propagated to the write track SOT on which the pillar MTJ rests. The pillar MTJ thus sees a potential difference at its terminals almost equal to V_{read}. A read current can then be established with an intensity that depends on the resistive state of the pillar MTJ. The read current is the sum of two currents: a first current injected from the first electrode EL1, and a second current from the second electrode EL2. Finally, all the control voltages VBL, VBLB and VRBL are progressively reset to zero and the selectors go to an off state to end the read operation. The advantage of this read mode is that when reading, two opposite currents flow through the write track SOT, eliminating the possibility of accidental writing.

FIG. 3e illustrates the steps of a second mode of reading the memory cell 10 according to the invention. The control circuit CONT is configured to apply at the same time: a second control voltage VBL=V_{read} such that Vth<V_{read}<2×Vth, a third control voltage VBLB=½ V_{read} and a first control voltage VRBL of zero to the upper end of the pillar MTJ. The first selector S1 switches to an on state while the second selector remains in an off state. The potential V_{read} is propagated to the write track SOT on which the pillar MTJ rests. The pillar thus sees a potential difference at its terminals almost equal to V_{read}. A read current can then be established with an intensity that depends on the resistive state of the pillar MTJ. The read current is injected only from the first electrode EL1. Finally, all the control voltages VBL, VBLB and VRBL are gradually reset to zero and the selectors go to an off state to end the read operation.

Other read modes are compatible with the memory cell 10 according to the invention. Table 2 summarizes the various read modes according to the invention compatible with the memory cell 10:

| Write mode | condition | VRBL | VBL | VBLB |
|---|---|---|---|---|
| 1^{st} mode | V_{read} > Vth | 0 | V_{read} | V_{read} |
| 2^{nd} mode | V_{read} > Vth | 0 | V_{read} | ½ V_{read} |
| 3^{rd} mode | Vth < V_{read} < 2xVth | 0 | ½ V_{read} | V_{read} |
| 4^{th} mode | V_{read} > Vth | V_{read} | 0 | 0 |
| 5^{th} mode | V_{read} > Vth | V_{read} | 0 | ½ V_{read} |
| 6^{th} mode | Vth < V_{read} < 2xVth | V_{read} | ½ V_{read} | 0 |

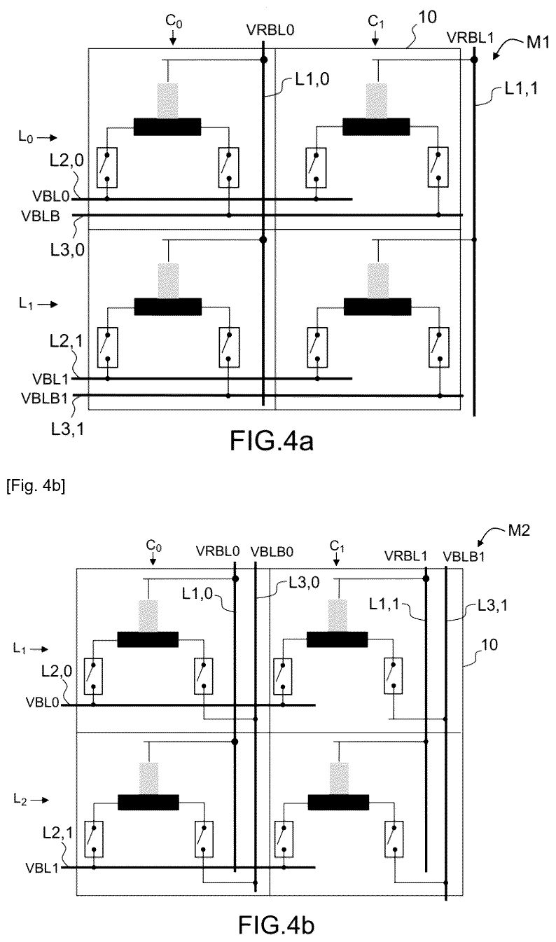

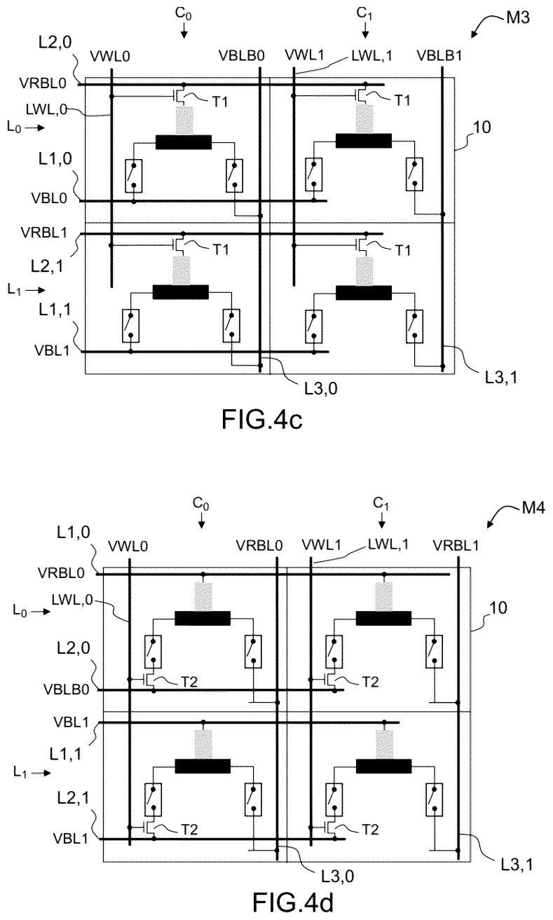

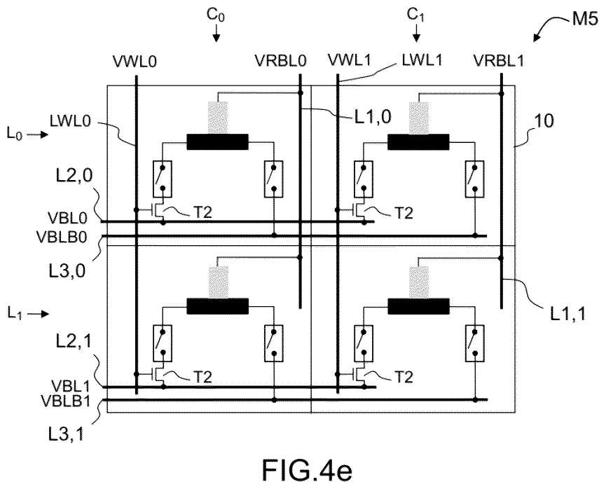

FIG. 4a shows an electrical diagram of a memory matrix M1 used in the memory circuit D1 according to a first embodiment of the invention.

The memory matrix M1 is formed by a plurality of memory cells 10 according to the invention arranged in rows Lᵢ and columns Cₖ, i=0 to N and k=0 to M. By way of illustration and not as a limitation, the matrix M1 is formed by two rows L₀, L₁ and two columns C₀ and C₁.

The ends of the magnetic tunnel junctions MTJ of the memory cells 10 belonging to the same column Cₖ of the memory matrix M1 are interconnected via a first conductive line L1,k intended to propagate the first control voltage VRBLₖ associated with said column Cₖ. The first electrodes EL1 of the memory cells 10 belonging to the same row Lᵢ of the memory matrix M1 are interconnected via a second conductive line L2,i intended to propagate the second control voltage VBLᵢ associated with said row. The second electrodes EL2 of the memory cells 10 belonging to the same row of the memory matrix M1 are interconnected via a third conductive line L3,i intended to propagate the associated third control voltage VBLBᵢ.

This matrix architecture is compatible with the first and second write modes described above and with the six read modes described above.

Table 3 illustrates the application of the two asynchronous write modes described above to the architecture of the matrix M1 of memory cells.

| Write | Logic | Selected cell | | | Non-selected cells | | |
|---|---|---|---|---|---|---|---|
| mode | state | VRBL | VBL | VBLB | VRBL | VBL | VBLB |
| 1^{st} mode | 0 | 0 | V_{prog} | 0 | ½ V_{prog} | 0 | 0 |
| 1^{st} mode | 1 | 0 | 0 | V_{prog} | ½ V_{prog} | 0 | 0 |
| 2^{nd} mode | 0 | V_{prog} | V_{prog} | 0 | ½ V_{prog} | V_{prog} | V_{prog} |
| 2^{nd} mode | 1 | V_{prog} | 0 | V_{prog} | ½ V_{prog} | V_{prog} | V_{prog} |

Table 4 illustrates the application of the six read modes described above to the architecture of the matrix M1 of memory cells.

| | Selected cell | | | Non-selected cells | | |
|---|---|---|---|---|---|---|
| Read mode | VRBL | VBL | VBLB | VRBL | VBL | VBLB |
| 1^{st} mode | 0 | V_{read} | V_{read} | ½ V_{read} | 0 | 0 |
| 2^{nd} mode | 0 | V_{read} | ½ V_{read} | ½ V_{read} | 0 | 0 |
| 3^{rd} mode | 0 | ½ V_{read} | V_{read} | ½ V_{read} | 0 | 0 |
| 4^{th} mode | V_{read} | 0 | 0 | ½ V_{read} | V_{read} | V_{read} |
| 5^{th} mode | V_{read} | 0 | ½ V_{read} | ½ V_{read} | ½ V_{read} | ½ V_{read} |
| 6^{th} mode | V_{read} | ½ V_{read} | 0 | ½ V_{read} | ½ V_{read} | ½ V_{read} |

FIG. 4b shows an electrical diagram of a memory matrix used in the memory circuit according to a second embodiment of the invention.

The memory matrix M2 is formed by a plurality of memory cells 10 according to the invention arranged in rows Lᵢ and columns Cₖ, i=0 to N and k=0 to M. By way of illustration and not as a limitation, the matrix M1 is formed by 2 rows L₀, L₁ and 2 columns C₀ and C₁.

The ends of the magnetic tunnel junctions MTJ of the memory cells 10 belonging to the same column Cₖ of the memory matrix M1 are interconnected via a first conductive line L1,k intended to propagate the first control voltage VRBLₖ associated with said column Cₖ. The first electrodes EL1 of the memory cells 10 belonging to the same row Lᵢ of the memory matrix M1 are interconnected via a second conductive line L2,i intended to propagate the second control voltage VBLᵢ associated with said row. The second electrodes EL2 of the memory cells 10 belonging to the same column Cₖ of the memory matrix M1 are interconnected via a third conductive line L3,k designed to propagate the associated third control voltage VBLBₖ.

This matrix architecture is compatible with the first write mode previously described for writing a first logic state “0”, with the second write mode previously described for writing the complementary logic state “1”, and with the six read modes previously described.

Table 5 illustrates the application of the first asynchronous write mode described above to the architecture of the pixel matrix M2.

| Write | Logic | Selected cell | | | Non-selected cells | | |
|---|---|---|---|---|---|---|---|
| mode | state | VRBL | VBL | VBLB | VRBL | VBL | VBLB |
| 1^{st} mode | 0 | 0 | V_{prog} | 0 | ½ V_{prog} | 0 | 0 |
| 2^{nd} mode | 1 | V_{prog} | 0 | V_{prog} | ½ V_{prog} | ½ V_{prog} | ½ V_{prog} |

Table 6 illustrates the application of the second and fifth read modes described above to the architecture of the pixel matrix M2.

| | Selected cell | | | Non-selected cells | | |
|---|---|---|---|---|---|---|
| Read mode | VRBL | VBL | VBLB | VRBL | VBL | VBLB |
| 2^{nd} mode | 0 | V_{read} | ½ V_{read} | ½ V_{read} | 0 | 0 |
| 5^{th} mode | V_{read} | 0 | ½ V_{read} | ½ V_{read} | ½ V_{read} | ½ V_{read} |

FIG. 4c shows an electrical diagram of a memory array used in the memory circuit according to a third embodiment of the invention. The memory matrix M3 is formed by a plurality of memory cells 10 according to the invention arranged in rows Lᵢ and columns Cₖ, i=0 to N and k=0 to M. By way of illustration and not as a limitation, the matrix M1 is formed by 2 rows L₀, L₁ and 2 columns C₀ and C₁. Each memory cell also comprises a control transistor T1. The source of the control transistor T1 is connected to the upper end of the magnetic tunnel junction MTJ. The gate of each transistor T1 is controlled by a selection signal VWL generated by the control circuit CONT.

The gates of the control transistors T1 of the memory cells 10 belonging to the same column Cₖ of the memory matrix M3 are interconnected via a conductive line LWL,k for propagating an associated selection signal VWLₖ. The drains of the control transistors T1 of the memory cells 10 belonging to the same row Lᵢ of the memory matrix M3 are interconnected via a conductive line L2,i intended to propagate the associated first control voltage VRBL,i. The first electrodes EL1 of the memory cells 10 belonging to the same row Lᵢ of the memory matrix M3 are interconnected via a second conductive line L1,i intended to propagate the second control voltage VBLᵢ associated with said row. The second electrodes EL2 of the memory cells 10 belonging to the same column Cₖ of the memory matrix M3 are interconnected via a conductive line L3,i intended to propagate the associated third control voltage VBLBₖ.

The integration of selection transistors T1 in the memory cells makes it possible to isolate the memory cells not selected for a read or write operation by imposing a zero voltage on the gate of the selection transistor T1. A memory cell is selected for reading or writing by applying the supply voltage VDD to the gate of the transistor T1 associated with said memory cell. The memory matrix M3 in the third embodiment is compatible with the three write modes (asynchronous and synchronous) and the six read modes described above.

FIG. 4d shows an electrical diagram of a memory matrix used in the memory circuit according to a fourth embodiment of the invention.

The memory matrix M4 is formed by a plurality of memory cells 10 according to the invention arranged in rows Lᵢ and columns Cₖ, i=0 to N and k=0 to M. By way of illustration and not as a limitation, the matrix M4 is formed by 2 rows L₀, L₁ and 2 columns C₀ and C₁. Each memory cell also comprises an attenuation transistor T2. The drain of said attenuation transistor T2 is connected to the first electrode EL1. The gate of each transistor T2 is controlled by a selection signal VWL generated by the control circuit CONT.

The gates of the attenuation transistors T2 of the memory cells 10 belonging to the same column Cₖ of the memory matrix M4 are interconnected via a conductive line LWL,k intended to propagate the associated selection signal VWLₖ. The sources of the attenuation transistors T2 of the memory cells 10 belonging to the same row Lᵢ of the memory matrix M4 are interconnected via a conductive line L2,i intended to propagate the associated second control voltage VBL,i. The upper ends of the pillars MTJ of the memory cells 10 belonging to the same row Lᵢ of the memory matrix M4 are interconnected via a conductive line L1,i intended to propagate the first control voltage VRBLᵢ associated with said row. The second electrodes EL2 of the memory cells 10 belonging to the same column Cₖ of the memory matrix M4 are interconnected via a conductive line L3,i intended to propagate the associated third control voltage VBLBₖ.

The integration of attenuation transistors T2 in the memory cells makes it possible to isolate the memory cells not selected for a read or write operation by imposing a zero voltage on the gate of the attenuation transistor T2. A memory cell is selected for reading or writing by applying the supply voltage VDD to the gate of the transistor T2 associated with said memory cell. In addition, modulation of the voltage applied to the gate of the attenuation transistor T2 makes it possible to attenuate the amplitude of the write and/or read current so as to improve the technical robustness of the memory cell and prevent accidental writes. The memory matrix M4 according to the fourth embodiment is compatible with the three write modes (asynchronous and synchronous) and the six read modes described above.

FIG. 4e shows an electrical diagram of a memory matrix used in the memory circuit according to a fifth embodiment of the invention.

The memory matrix M5 according to the fifth embodiment has the same characteristics and advantages as the memory matrix according to the fourth embodiment. The memory matrix M5 is distinguished from the memory matrix M4 by an inversion between, on the one hand, the conductive line intended to propagate the first control voltage VRBL (common to cells in the same column in M5) and, on the other hand, the conductive line intended to propagate the third control voltage VBLB (common to cells in the same row in M5).

The memory matrix M5 in the fifth embodiment is compatible with the three write modes (asynchronous and synchronous) and the six read modes described above.

### REFERENCES

[1]: Rana Alhalabi, Etienne Nowak, loan-Lucian Prejbeanu, Gregory Di Pendina. High density SOTMRAM memory array based on a single transistor. Non-Volatile Memory Technology Symposium (NVMTS), October 2018, Sendai, Japan.

1. A magnetoresistive memory cell comprising:
a pillar (MTJ) forming a magnetic tunnel junction (MTJ) and having an upper end for receiving a first control voltage (VRBL) and a lower end;
a write track (SOT) made of a spin Hall effect material or an orbital Hall effect material; the pillar (MTJ) being arranged on said write track at its lower end;
a support layer made of a material having a configurable metal-insulator transition; the support layer having a first face and an opposite second face;
the write track (SOT) being disposed on said first face;
a first electrode (EL1) arranged on said second face and intended to receive a second control voltage (VBL); the part of the support layer confined between the first electrode (EL1) and the write track (SOT) having a conduction state configurable by the first and second control voltages (VRBL, VBL) so as to form a first selector (S1) having a high resistive state (R1_{OFF}) and a low resistive state (R1_{ON});
a second electrode (EL2) arranged on said second face and intended to receive a third control voltage (VBLB); the part of the support layer confined between the second electrode (EL2) and the write track (SOT) having a conduction state configurable by the first and third control voltages (VRBL, VBLB) so as to form a second selector (S2) having a high resistive state (R2_{OFF}) and a low resistive state (R2_{ON}).

2. The magnetoresistive memory cell according to claim 1, wherein the support layer is made of Mott oxide or a topological insulator.

3. The magnetoresistive memory cell according to claim 2, wherein at least one of the confined parts of the support layer is doped by chromium or by tungsten or by titanium or by aluminium or by iron or by molybdenum or by tantalum or by ruthenium or by zirconium.

4. The magnetoresistive memory cell according to claim 1, wherein the write track (SOT) is made of a spin Hall effect material chosen from beta phase tungsten or bismuth antimonide or a BiSbTe alloy.

5. The magnetoresistive memory cell according to claim 1, wherein the write track (SOT) is made of an orbital Hall effect material chosen from chromium or zirconium or titanium or vanadium or copper or manganese or molybdenum or ruthenium or aluminium or niobium or tungsten in alpha phase.

6. The magnetoresistive memory cell according to claim 1, wherein the write track (SOT) has a thickness less than or equal to 20 nm.

7. The magnetoresistive memory cell according to claim 1, wherein the first and/or second selector (S1, S2) has a resistance greater than or equal to 10 times the resistance of the write track (SOT) when said selector (S1, S2) is in a high resistive state (R1_{OFF}, R2_{OFF}).

8. The magnetoresistive memory cell according to claim 1, wherein the first and/or second selector (S1, S2) has a resistance greater than or equal to 10 times the resistance of the magnetic tunnel junction (MTJ) when said selector (S1, S2) is in a high resistive state (R1_{OFF}, R2_{OFF}).

9. The magnetoresistive memory cell according to claim 1, wherein the first and/or second selector (S1, S2) has a resistance less than or equal to the resistance of the write track (SOT) when said selector (S1, S2) is in a low resistive state (R1_{ON}, R2_{ON}).

10. The magnetoresistive memory cell according to claim 1, wherein the first and/or second selector (S1, S2) has a resistance less than or equal to one tenth of the resistance of the magnetic tunnel junction (MTJ) when said selector (S1, S2) is in a low resistive state (R1_{ON}, R2_{OFF}).

11. The magnetoresistive memory cell according to claim 1 further comprising a control transistor (T1); the source of said control transistor (T1) being connected to the upper end of the pillar (MTJ).

12. The magnetoresistive memory cell according to claim 1 further comprising an attenuation transistor (T2); the drain of said attenuation transistor (T2) being connected to the first electrode (EL1).

13. The magnetoresistive memory cell according to claim 1, wherein the first and/or second selector (S1, S2) is adapted to pass from a high resistive state (R1_{OFF}, R2_{OFF}) to a low resistive state (R1_{ON}, R2_{ON}) when the amplitude of the voltage at the terminals of said selector is greater than a predetermined threshold voltage (Vth).

14. A memory circuit (D1) comprising:
a memory matrix (Mx) formed by a plurality of memory cells according to claim 13;
a control circuit (CONT) configured to generate the first control voltage (VRBL), the second control voltage (VBL) and the third control voltage (VBLB).

15. The memory circuit (D1) according to claim 14, wherein the control circuit (CONT) is configured to perform a write operation on a memory cell of the matrix (Mx) by applying:
a first control voltage (VRBL) of zero, a second control voltage (VBL) greater than the predetermined threshold voltage (Vth) and a third control voltage (VBLB) of zero to write a first logic state;
a first control voltage (VRBL) of zero, a second control voltage (VBL) of zero and a third control voltage (VBLB) greater than the predetermined threshold voltage (Vth) to write a second logic state complementary to the first logic state.

16. The memory circuit (D1) according to claim 14, wherein the control circuit (CONT) is configured to perform a write operation on a memory cell of the matrix (Mx) by applying:
a first control voltage (VRBL) greater than the predetermined threshold voltage (Vth), a second control voltage (VBL) equal to the first control voltage (VRBL) and a third control voltage (VBLB) of zero to write a first logic state;
a first control voltage (VRBL) greater than the predetermined threshold voltage (Vth), a second control voltage (VBL) of zero and a third control voltage (VBLB) equal to the first control voltage (VRBL) to write a second logic state complementary to the first logic state.

17. The memory circuit (D1) according to claim 14, wherein the control circuit (CONT) is configured to perform a write operation on a memory cell of the matrix (Mx) by applying:
a second control voltage (VBL) greater than twice the predetermined threshold voltage (Vth); a first control voltage (VRBL) equal to half the second control voltage (VBL) and a third control voltage (VBLB) of zero to write a first logic state;
a third control voltage (VBLB) greater than twice the predetermined threshold voltage (Vth); a first control voltage (VRBL) equal to half the third control voltage (VBL) and a second control voltage (VBL) of zero to write a second logic state complementary to the first logic state.

18. The memory circuit (D1) according to claim 14, wherein the control circuit (CONT) is configured to perform a read operation on a memory cell of the memory matrix (Mx) by applying to it a second and a third control voltage (VBL, VBLB) greater than the predetermined threshold voltage (Vth) and a first control voltage (VRBL) of zero.

19. The memory circuit (D1) according to claim 14, wherein:
the upper ends of the pillars (MTJ) of the memory cells belonging to the same column of the memory matrix (M1) are interconnected via a first conductive line (L1,0; L1,1) intended to propagate the associated first control voltage (VRBL₀, VRBL₁);
the first electrodes (EL1) of the memory cells belonging to the same row of the memory matrix (M1) are interconnected via a second conductive line (L2,0; L2,1) intended to propagate the associated second control voltage (VBL₀, VBL₁);
the second electrodes (EL2) of the memory cells belonging to the same row of the memory matrix (M1) are interconnected via a third conductive line (L3,0; L3,1) intended to propagate the associated third control voltage (VBLB₀, VBLB₁).

20. The memory circuit (D1) according to claim 14, wherein:
the upper ends of the pillars (MTJ) of the memory cells belonging to the same column of the memory matrix (M2) are interconnected via a first conductive line (L1,0; L1,1) intended to propagate the associated first control voltage (VRBL₀, VRBL₁);
the first electrodes (EL1) of the memory cells belonging to the same row of the memory matrix (M2) are interconnected via a second conductive line (L2,0; L2,1) intended to propagate the associated second control voltage (VBL₀, VBL₁);
the second electrodes (EL2) of the memory cells belonging to the same column of the memory matrix (M2) are interconnected via a third conductive line (L3,0; L3,1) intended to propagate the associated third control voltage (VBLB₀, VBLB₁).

21. The memory circuit (D1) according to claim 14, further comprising a control transistor (T1); the source of said control transistor (T1) being connected to the upper end of the pillar (MTJ), and
wherein:
the gates of the control transistors (T1) of the memory cells belonging to the same column of the memory matrix (M3) are interconnected via a first conductive line (LWL,0; LWL,1) intended to propagate an associated selection signal (VWL₀, VWL₁);
the drains of the control transistors (T1) of the memory cells belonging to the same row of the memory matrix (M3) are interconnected via a second conductive line (L2,0; L2,1) intended to propagate the associated first control voltage (VRBL₀, VRBL₁);
the first electrodes (EL1) of the memory cells belonging to the same row of the memory matrix (M3) are interconnected via a third conductive line (L1,0; L1,1) intended to propagate the associated second control voltage (VBL₀, VBL₁);
the second electrodes (EL2) of the memory cells belonging to the same column of the memory matrix (M3) are interconnected via a fourth conductive line (L3,0; L3,1) intended to propagate the associated third control voltage (VBLB₀, VBLB₁).

22. The memory circuit (D1) according to claim 14, further comprising an attenuation transistor (T2); the drain of said attenuation transistor (T2) being connected to the first electrode (EL1), and
wherein:
the upper ends of the pillars (MTJ) of the memory cells belonging to the same row of the memory matrix (M4) are interconnected via a first conductive line (L1,0; L1,1) intended to propagate the associated first control voltage (VRBL₀, VRBL₁);
the sources of the attenuation transistors (T2) of the memory cells belonging to the same row of the memory matrix (M4) are interconnected via a second conductive line (L2,0; L2,1) intended to propagate the associated second control voltage (VBL₀, VBL₁);
the second electrodes (EL2) of the memory cells belonging to the same column of the memory matrix (M4) are interconnected via a third conductive line (L3,0; L3,1) intended to propagate the associated third control voltage (VBLB₀, VBLB₁);
the gates of the attenuation transistors (T2) of the memory cells belonging to the same column of the memory matrix (M4) are interconnected via a fourth conductive line (LWL0; LWL1) intended to propagate an associated selection signal (VWL₀, VWL₁).

23. The memory circuit (D1) according to claim 14, further comprising an attenuation transistor (T2); the drain of said attenuation transistor (T2) being connected to the first electrode (EL1), and
wherein:
the upper ends of the pillars (MTJ) of the memory cells belonging to the same column of the memory matrix (M5) are interconnected via a first conductive line (L1,0; L1,1) intended to propagate the associated first control voltage (VRBL₀, VRBL₁);
the sources of the attenuation transistors (T2) of the memory cells belonging to the same row of the memory matrix (M5) are interconnected via a second conductive line (L2,0; L2,1) intended to propagate the associated second control voltage (VBL₀, VBL₁);
the second electrodes (EL2) of the memory cells belonging to the same row of the memory matrix (M3) are interconnected via a third conductive line (L3,0; L3,1) intended to propagate the associated third control voltage (VBLB₀, VBLB₁);
the gates of the control transistors (T2) of the memory cells belonging to the same column of the memory matrix (M3) are interconnected via a fourth conductive line (LWL0; LWL1) intended to propagate an associated selection signal (VWL₀, VWL₁).
